(19) United States
(12) Patent Application Publication
(10) Pub. No.: US 2010/0164125 A1
(43) Pub. Date: Jul. 1, 2010

(54) METHOD OF EVALUATING THE FLAME RETARDANCY OF SEALING RESIN AND TEST SAMPLE FOR EVALUATION OF FLAME RETARDANCY

(75) Inventors: Kizashi Tanioka, Miyawaka-shi (JP); Masanori Okamoto, Kawaguchi-shi (JP); Akiko Suda, Kawaguchi-shi (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/640,673

(22) Filed: Dec. 17, 2009

(30) Foreign Application Priority Data
Dec. 25, 2008 (JP) 2008-330005

(51) Int. Cl. H01L 23/28; G01N 25/00; H01L 21/56

(52) U.S. Cl. 257/787; 374/8; 438/127; 257/784; 257/E23.116; 257/E21.502

(57) ABSTRACT

A method of evaluating the flame retardancy of a sealing resin comprises a step of fusion cutting a heating element by causing the heating element to generate heat by the passage of electric current to a test sample of a molded body of the sealing resin including the heating element therein; a step of igniting the sealing resin by continuing the passage of electric current even after the heating element is fusion-cut; and a step of measuring voltage and/or current applied in a period from when the heating element is fusion-cut to the ignition of the sealing resin. The test sample is used in the method of evaluating the flame retardancy and provided with a heating wire; conducting terminals made of metal having an electric resistance lower than the heating wire and connected to both ends of the heating wire; and a sealing resin layer covering the outer periphery of the heating wire. The evaluation can be performed on the flame retardancy of the sealing resin used for the electronic equipment based on its actual use.

### CROSS REFERENCE TO RELATED APPLICATIONS

This application is based upon and claims the benefit of priority from the prior Japanese Patent Application No. 2008-330005 filed on Dec. 25, 2008; the entire contents of which are incorporated herein by reference.

### BACKGROUND OF THE INVENTION

In recent years, it is demanded to reduce the thickness and size of electronic devices including semiconductor devices. Therefore, a sealing resin for protecting elements and wires tends to be reduced in volume. From the viewpoint of reduction in the environmental load, it is considered to shift from a mode that a bromine type flame retardant and antimony trioxide are used to impart flam retardancy to the sealing resin to a mode that an alternative nonhalogen flame retardant is used or a flame retardant is not used.

The above movement becomes a factor to accelerate generation of smoke or fire when the sealing resin burns combined with the volume reduction of the sealing resin, and a method of evaluating the flame retardancy of the sealing resin is becoming important more and more.

As a test for evaluating the flame retardancy of the sealing resin, there have been proposed a UL-94 standard, a high current arc ignition (HAI) test, a hot wire ignition (HWI) test and the like. All the above tests employ a method of heating (giving a heat source) a molded body of the sealing resin from outside. But, the ignition of actual electronic equipment does not necessarily result from the exposure to generation of heat from outside. Therefore, the above test methods do not evaluate the flame retardancy of the sealing resin in actual use.

Conventionally, there is proposed that a heating circuit is mounted on a semiconductor package which has a resin sealed structure, a semiconductor element (chip) is caused to generate heat by the heating circuit, and the smoke-generating property of the sealing resin is evaluated by measuring an amount of smoke, which is produced from the sealing resin by the generation of heat of the semiconductor element, electric power consumption and an elapsed time (see for example JP-A 02-232552 (KOKAI)).

But, the above method has a difficulty in collecting the produced smoke efficiently and needs a very high cost device to measure the amount of produced smoke quantitatively. And, to evaluate a sealing resin which is composed of different materials, it is also necessary to pay adequate attention to the components of the produced smoke. Therefore, there is a problem that the test device becomes large in scale.

In addition, a mechanism leading to smoking and igniting of the sealing resin in an actual semiconductor package is not generation of heat from the semiconductor element, but fusion cutting of the bonding wire and generation of heat through a cabonized portion in the sealing resin produced as a result of the fusion cutting as described later. Therefore, there was a problem that if the bonding wire is deformed due to a difference in flow property of the sealing resin, the thickness of the sealing resin from a heating source is variable to influence on the test result, thereby resulting to be a cause of an error.

When a situation is considered that heat is generated from the inside of the semiconductor package to cause smoking and firing as a result, the heat generation portion is blocked from outside air (oxygen) by the sealing resin in the early stage of the heat generation, but the sealing resin is partly broken by volume expansion of the sealing resin or an increase in inner pressure involved in generation of decomposition gas as heating progressed, and air (oxygen) is supplied.

To evaluate the flame retardancy of the sealing resin, it is necessary to consider various physical properties such as toughness and ductility at the time of heating in addition to flammability of the resin. Therefore, the test method of heating from outside cannot indicate the flame retardancy by an index adequately. An event, which must be avoided most, for the semiconductor package is burning (ignition) accompanied by flame, and if ignition occurs, fire spreads easily to the peripheral parts, substrate and resin enclosure. Accordingly, a test method having as an index an ignition phenomenon which occurs in a real product is desired.

### SUMMARY OF THE INVENTION

A method of evaluating the flame retardancy of a sealing resin according to a first aspect of the present invention comprises heating and fusion cutting a heating element of a test sample by passing electric current to the heating element to cause the heating element to generate heat, the test sample having a layer formed of the sealing resin including the heating element therein; igniting the sealing resin by continuing the passage of electric current to the heating element even after the heating element is fusion-cut; and measuring a voltage and/or current applied in a period from the fusion cutting of the heating element to the ignition of the sealing resin.

A test sample for evaluation of flame retardancy according to a second aspect of the present invention is used in the method of evaluating according to a first aspect of the present invention, comprises a heating wire; conducting terminals formed of metal having an electric resistance lower than the heating wire and connected to both ends of the heating wire; and a sealing resin layer covered on the outer periphery of the heating wire and a portion of the each conducting terminal.

A semiconductor device according to a third aspect of the present invention comprises a substrate; a semiconductor chip mounted on the substrate; external connection terminals; bonding wires electrically connecting the semiconductor chip and the external connection terminals; and a sealing resin layer formed over the bonding wires and connection points between the bonding wires and the semiconductor chip, wherein the sealing resin layer is formed of the sealing resin which is evaluated as highly flame retardant by the method of evaluating the flame retardancy according to a first aspect of the present invention.

A method of producing a semiconductor device according to a forth aspect of the present invention, comprises mounting a semiconductor chip on a substrate;

electrically connecting the semiconductor chip and external connection terminals through bonding wires; and forming a sealing resin layer over the bonding wires and connection points between the bonding wires and the semiconductor chip, wherein the forming of the sealing resin layer has forming the sealing resin which is evaluated as highly flame retardant by the method of evaluating the flame retardancy according to a first aspect of the present invention.

### BRIEF DESCRIPTION OF THE DRAWINGS

FIG. 1A is a sectional view showing a semiconductor package which is undergone an overcurrent test and in a state before a cabonized portion is formed in a sealing resin.

FIG. 1B is a sectional view showing the semiconductor package which is undergone the overcurrent test and in a state that the cabonized portion is formed in the sealing resin.

FIG. 2 is a circuit diagram for illustrating a method of evaluating the flame retardancy of the sealing resin according to a first embodiment of the invention.

FIG. 3A is a vertical sectional view showing a test sample for evaluation of flame retardancy according to a second embodiment of the invention.

FIG. 3B is a sectional view taken along line A-A of the test sample for evaluation of flame retardancy shown in FIG. 3A.

FIG. 4 is a vertical sectional view showing a magnified state of a swaged (compression-bonded) portion of a heating element and a conducting terminal of the test sample for evaluation of flame retardancy according to the second embodiment.

FIG. 5 is a sectional view showing a structure of a semiconductor device according to a third embodiment of the invention.

FIG. 6 is a graph showing changes in voltage applied to the test sample according to an example of the invention.

FIG. 7 is a graph showing the measured results of the applied voltage and current values according to an example of the invention.

### DETAILED DESCRIPTION OF THE INVENTION

Modes of conducting the present invention will be described below. Embodiments of the present invention are described with reference to the drawings, which are provided for illustration only, and the present invention is not limited to the drawings.

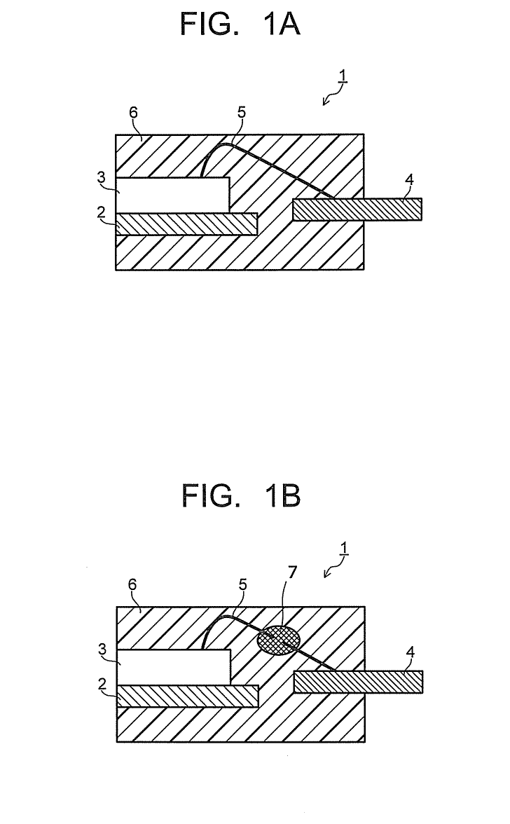

The inventors performed a test to cause smoking and ignition of the sealing resin by applying overcurrent to a semiconductor package 1 shown in FIG. 1A. From the results of analyzing the test, they found a mechanism leading to smoking and ignition due to heating started within the sealing resin.

The semiconductor package 1 used for the overcurrent test has a structure that a semiconductor chip 3, which is mounted on a substrate 2 such as a die stage, and an external connection terminal 4 are connected through a bonding wire (gold wire) 5, and a sealing resin layer 6 is formed to include the bonding wire (gold wire) 5 therein. In the semiconductor package 1, the bonding wire 5 is fusion-cut when overcurrent flows from the external connection terminal 4. Since the bonding wire 5 is caused to have a high temperature, the sealing resin around the bonding wire 5 is burned to form a cabonized portion 7 as shown in FIG. 1B. Therefore, even if the bonding wire 5 is fusion-cut, a circuit is formed through the cabonized portion 7 in the sealing resin. And, the passage of electric current to the semiconductor chip 3 is continued. Since the cabonized portion 7 of the sealing resin has a resistance value of several ohms (Ω), the surrounding sealing resin has an increased temperature due to heat generation of the cabonized portion 7 when the passage of electric current is continued. And, the sealing resin layer 6 has an increased high-temperature region to show burning behaviors such as smoking and glowing, and when the glowing portion comes into contact with the outside air (oxygen), burning accompanied by flame is caused, resulting in firing.

It was found from the above overcurrent test results that even if sealing resins meet the same V-0 grade of the UL-94 standard, they have a different possibility of ignition, and some of them ignite but some not.

Table 1 shows the results of conducting an overcurrent test, which passes a rated electric current or more to a motor driver IC. Both resin A and resin B are resins which have a biphenyl dimethylene type epoxy resin as a base compound and a biphenyl dimethylene type phenol resin as a curing agent and are free from a flame retardant. They also contain silica at a ratio of 89 wt %. Differences between the resin A and the resin B are only compounding amounts of components such as a release agent, a coupling agent, an adhesion promoter and a stress additive which are contained in minute amounts. Resin C is a resin having an orthocresol type epoxy resin as a base compound and a phenol novolak resin as a curing agent, and a brominated epoxy resin (tetrabromo-bisphenol A type epoxy resin) is compounded as a flame retardant. And, antimony trioxide is compounded as a flame retardant aid. The compounding amount of silica is 84 wt %.

TABLE 1

| | | Resin A | Resin B | Resin C |
|---|---|---|---|---|
| Ignition | Keep burning | 1 | | |
| | After fire | 2 | | |
| | extinction, | | | |
| | reignition | | | |
| | After fire | | | 1 |
| | extinction, | | | |
| | smoking only | | | |
| | After fire | | 3 | |
| | extinction, no | | | |
| | passage of | | | |
| | current | | | |
| No | Smoking only | | 1 | 2 |
| ignition | After sparking, | | 1 | 2 |
| | no passage of | | | |
| | current | | | |

| | | | |
|---|---|---|---|
| Number of tests | 3 | 5 | 5 |

The resins A, B and C have the V-0 grade of the UL-94 standard, but as shown in Table 1, the results of the test (overcurrent test) of ignition in the sealing resin by applying overcurrent are largely variable depending on the resin types, and the resin A is most likely to ignite and followed by the resin B and the resin C. Thus, the result that the resin C was most unlikely to ignite was obtained.

Embodiments of the present invention are described below.

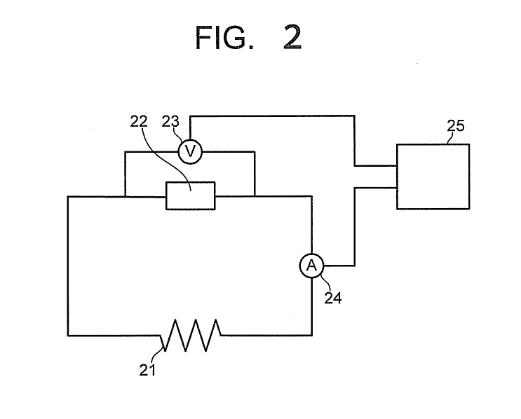

FIG. 2 is a circuit diagram for illustrating a method of evaluating the flame retardancy of a sealing resin according to a first embodiment of the invention. A molded body of the sealing resin having sealed a heating element with the sealing resin is determined as a test sample 21 in the first embodiment. The test sample 21 is connected to a variable power source 22 capable of varying the applied voltage, and electric current is passed to the heating element within the test sample 21. The passage of electric current causes the heating element to generate heat. The passage of electric current is continued even after the heating element is fusion-cut, and the applied voltage and current before the sealing resin ignites (combustion accompanied by flame) by heating from the inside are measured by a voltmeter 23 and an ammeter 24. And, the measured values of voltage and current are recorded and an amount of electric power (voltage×current) is calculated by a recorder/calculator 25 connected to the voltmeter 23 and the ammeter 24.

The determined amount of electric power needed from the fusion cutting of the heating element to the ignition of the sealing resin is used as an index indicating the flame retardancy of the sealing resin. The flame retardancy can be evaluated for its level according to the index whether or not the sealing resin tends to ignite by heating from its inside. It is preferable that the amount of electric power (voltage×current) is used as an index for evaluation of the flame retardancy, but it is also possible to evaluate the flame retardancy from at least one of the measured voltage and current values.

In comparison with a conventional method of performing a test by using the semiconductor package as it is, the method of evaluating the flame retardancy of the first embodiment configured as described above can indicate the flame retardancy of the sealing resin by an index quantitatively and can evaluate without being influenced by various causes of error such as a size of the package, a diameter and length of the bonding wire and a change in thickness of the resin layer due to deformation of the bonding wire when the sealing resin layer is formed. And, it becomes possible to evaluate the flame retardancy by an embodiment close to a real product or real use in comparison with the conventional method of testing the flame retardancy by heating from outside.

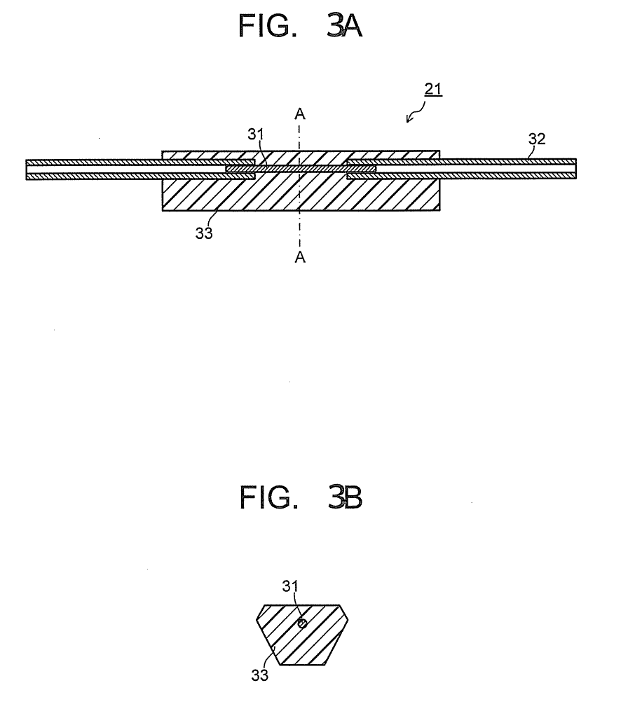

The test sample used in the method of evaluating the flame retardancy of the first embodiment is described below. The test sample 21 according to a second embodiment of the invention has a linear heating element 31 made of metal having a high electric resistance, conducting terminals 32 connected to both ends of the heating element 31, and a sealing resin layer 33 which is covered and formed on the outer periphery of the heating element 31 as shown in FIG. 3A and FIG. 3B.

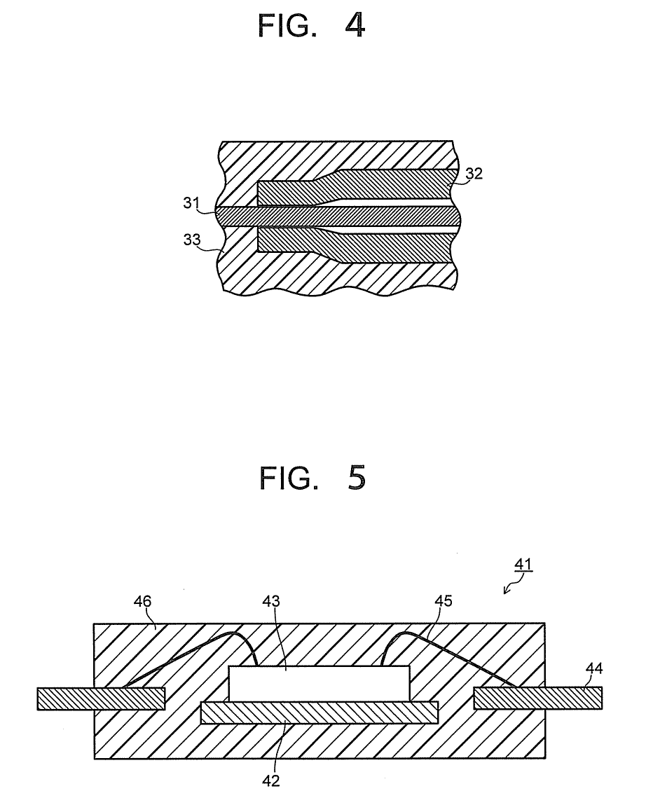

The heating element 31 has a strength enough not to be deformed when its outer periphery portion is covered with the sealing resin. The heating element 31 is desirably a small-diameter linear body because it is required to be fusion-cut when testing. Examples of the heating element include a heating wire such as a nichrome wire, a kanthal wire or a tungsten wire. The conducting terminal 32 is made of a tube or a rod of metal having an electric resistance lower than the material configuring the heating element 31, such as copper, silver, gold, aluminum or an alloy thereof. The each metallic tube configuring the conducting terminal 32 is electrically connected stably to both ends of the heating element 31 as shown in a magnified form in FIG. 4 by swaging (compression-bonding). The metallic tube may also be connected to the heating element 31 by a method such as welding or brazing. The rod-like conducting terminal may be connected to the heating element 31 by welding.

When the metallic tube as the conducting terminal 32 is not connected to the heating element 31 but it is configured to pass electric current directly to both ends of the heating element 31, ignition occurs easily from the outer periphery wall of the sealing resin layer 33 which is in contact with the conducting end portion to the heating element 31, and an ignition event due to internal heating cannot be reproduced. When the metallic tube having an electric resistance lower in comparison with the heating element 31 is connected as the conducting terminal 32 to the heating element 31, there are advantages that ignition and burning can be caused with a good reproducibility at a prescribed portion (center) of the sealing resin layer 33, and it is easy to observe when the ignition occurs.

The layer 33 formed of the sealing resin which is a subject to be tested is formed and coated by transfer molding or the like on the outer periphery of the heating element 31 both ends of which are connected with the conducting terminals 32. It is preferable that the sealing resin layer 33 has a thickness which is not constant in a whole circumferential direction of the heating element 31 but made thinner at one side (e.g., upper side) than the other side (e.g., lower side). It is preferable that the thicker portion (e.g., lower side) of the layer is formed to be 2 to 5 times larger than the thinner portion (e.g., upper side). By forming in this way, ignition can be occurred efficiently at a given portion only of the thin layer portion. Therefore, burning behavior (ignition) can be observed easily.

It is preferable that the thickness of a given portion of the sealing resin layer 33, which is observed for the burning behavior, is determined by performing a preliminary examination. If the portion which is observed for ignition is excessively thin, the ignition is excessively quick and if it is excessively thick, there is a possibility that the ignition does not occur at all because oxygen required for burning from the inside cannot be supplied. Therefore, it is difficult in each case that an amount of electric power up to the ignition is determined as an index for evaluation of the flame retardancy.

For the sealing resin, there was prepared a resin which had a biphenyl dimethylene type epoxy resin as a base compound and a biphenyl dimethylene type phenol resin as a curing agent without blending a flame retardant. And, the method of evaluating the flame retardancy described in the first embodiment was preliminarily performed with the thickness of the sealing resin layer varied in a range of from 1.0 mm to 1.6 mm by 0.2 mm at a time to examine ignition rates. The obtained results are shown in Table 2.

TABLE 2

| Resin layer | | Times of | |
|---|---|---|---|
| thickness | Test samples | ignition | Ignition rate |
| 1.0 mm | 5 | 3 | 60% |
| 1.2 mm | 8 | 4 | 50% |
| 1.4 mm | 4 | 1 | 25% |
| 1.6 mm | 5 | 0 | 0% |

It was found from the results that the test samples of this type of sealing resin preferably have the thin portion (e.g., upper side) with a thickness of 1 to 1.2 mm on the side of the layer thickness for observation of ignition.

A semiconductor device using the sealing resin which was evaluated as highly flame retardant by the method of evaluating the flame retardancy of the first embodiment is described below. As shown in FIG. 5, a semiconductor device 41 according to a third embodiment of the invention is provided with a substrate 42 such as a die stage, a semiconductor chip 43 which is mounted on the substrate 42 with an element circuit side directed upward, external connection terminals 44 to which current is supplied from the outside, bonding wires 45 such as gold wires for connecting the semiconductor chip 43 and the external connection terminal 44, and a sealing resin layer 46 which is formed to include the semiconductor chip 43 and the bonding wires 45. And, the sealing resin layer 46 is formed of a sealing resin which was evaluated and judged as highly flame retardant as a result of performing the method of evaluating the flame retardancy of the above-described first embodiment.

The semiconductor device 41 is produced by mounting the semiconductor chip 43 on the substrate 32 and connecting an electrode pad (not shown) of the semiconductor chip 43 and the external connection terminals 44 through the bonding wires 45. Then, the sealing resin which was evaluated and judged as highly flame retardant by the method of evaluating the flame retardancy according to the first embodiment is formed to include the semiconductor chip 33 and the bonding wires 45 by transfer molding or the like to form the sealing resin layer 46.

For the obtained semiconductor device 41, the sealing resin of which high flame retardancy is evaluated under conditions based on the real product and actual use is used, so that a possibility of burning accompanied by ignition or smoking in actual use can be eliminated compared with the semiconductor device having the sealing resin which was evaluated by the conventional method. Therefore, a possibility of fire spreading to peripheral equipment, enclosure and the like can be eliminated completely.

Specific examples of the invention are described below.

In this example, nichrome wires having a diameter of 0.2 to 0.3 mm and a length of 10 to 30 mm were used as the heating element, and copper tubes having an outside diameter of 1.0 to 2.0 mm were connected to their both ends by swaging. After the swaging, voltage of 1.5V was applied to the connection points between the nichrome wire and the copper tubes, and their combinations having a resistance value which is not larger than a prescribed value and good electrical connection were selected.

Then, three types of sealing resins (1) to (3) shown in Table 3 were used to form a sealing resin layer on the outer periphery of the nichrome wires. Specifically, the each sealing resin was transfer-molded on the outer periphery of the nichrome wire at a temperature of 175 degrees C. and hardened (cured) by heating at 175 degrees C. for eight hours. Thus, the test sample 21 shown in FIG. 3A and FIG. 3B was produced. The sealing resins (2) and (3) shown in Table 3 are same as the resin C and resin B used for the overcurrent test of the motor driver IC in Table 1. The sealing resin (1) is an epoxy resin which has the same type of the base compound, curing agent and flame retardant as the sealing resin (2). The sealing resin (1) is not used for the overcurrent test because the motor driver IC could not be sealed well because of the properties of the resin.

TABLE 3

| | Sealing resin | Sealing resin | |
|---|---|---|---|
| | (1) | (2) | Sealing resin (3) |
| Base | Orthocresol novolak type | | Biphenyl dimethylene |
| compound | epoxy resin | | type epoxy resin |
| Curing | Phenol novolak resin | | Biphenyl dimethylene |
| agent | | | type phenol resin |
| Flame | Tetrabromo-bisphenol | | None |
| retardant | A type epoxy resin | | |
| | Antimony trioxide | | |
| Silica | 73 wt % | 84 wt % | 89 wt % |
| compounding | | | |
| amount | | | |
| Flame | V-0 | V-0 | V-0 |
| retardancy | | | |
| (UL94) | | | |

The obtained test sample 21 was incorporated into the circuit shown in FIG. 2, and its flame retardancy evaluation test was performed. As the variable power source 22, PAX35-20, a product of Kikusui Electronics Corporation, was used, and as the voltmeter 23 and the ammeter 24, a digital multimeter, a product of Sanwa Electric Instrument Co., Ltd., was used. And, as the recorder/calculator 25, a computer in which PC Link Plus, a product of Sanwa Electric Instrument Co., Ltd., was installed was used.

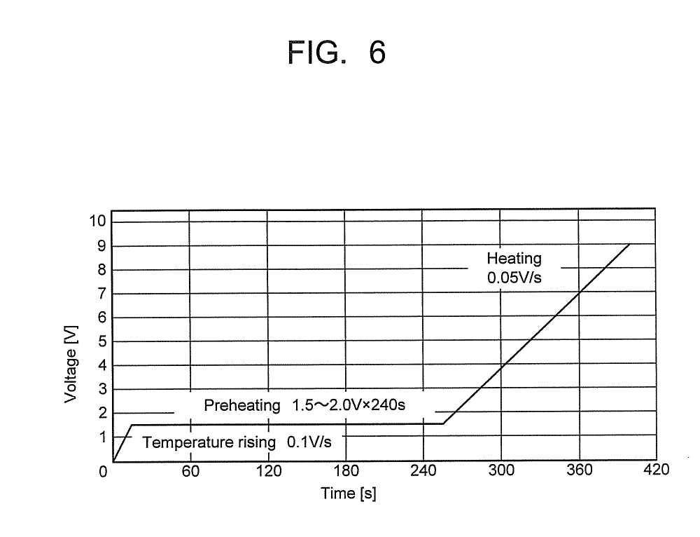

Voltage shown in the graph of FIG. 6 was applied to the test sample 21 over time in order to cause a nichrome wire used as the heating element to generate heat, thereby the sealing resin layer was heated from its inside. Even after the heating element was fusion-cut, the passage of electric current by the voltage application was continued, and the ignition of the sealing resin was observed. The voltage and current values in the heating step were measured and recorded by the recorder/calculator 25.

In the heating by the voltage application, it is preferable that a preheating step for preliminarily heating the sealing resin is provided before the actual heating (full scale heating) step. It is preferable that the voltage applied in the preheating step is determined to fall in a range determined by a method of performing a test in advance or the like. In the case that the voltage applied in the preheating step is excessively high, the preheating becomes excessive depending on a type of sealing resin and causes a large breakage having a crater shape, and burning (ignition) might not occur. when the applied voltage is excessively low, preheating is insufficient, and ignition might not be caused in the full scale heating step. Therefore, it is preferable to perform pretesting to determine the appropriate voltage for preheating conforming to the type of sealing resin. In addition, it is preferable that a voltage increasing rate of the applied voltage in the full scale heating is adjusted to a value to allow the passage of current by formation of the cabonized portion after the heating element is fusion-cut.

In the example, an appropriate voltage of 1.5 to 2.0V was determined from the results of the pretesting. The voltage was applied in the preheating step for 240 seconds. In the full scale heating, the applied voltage was raised at a speed of 0.05 V/s.

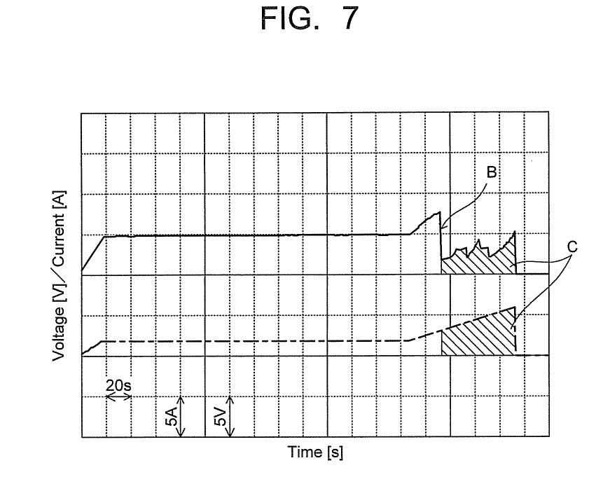

FIG. 7 is a graph showing the measured results of the applied voltage and current values in the preheating step and full scale heating step. The voltage change is indicated by an alternate long and short dash line, and the current change is indicated by a solid line. The voltage value was raised at a speed of 0.1 V/s from the start of the test to reach a preheating voltage, which was maintained for 240 seconds (preheating step). Then, the voltage was raised at a speed of 0.05 V/s in the full scale heating step. The current value was changed as the applied voltage-was changed as described above, but a nichrome wire as the heating element was fusion-cut (broken) in the middle of the full scale heating step, and the current value was lowered substantially (indicated by B in FIG. 7). But, since the cabonized portion resulting from the carbonization of the sealing resin contributes to the passage of electric current, the current value did not become 0. The test sample was removed just after the nichrome wire was fusion-cut, and the sealing resin around the nichrome wire was observed to find that the cabonized portion was formed.

In the example, time measurement was started by a stopwatch from the time when the nichrome wire was fusion-cut and the current value dropped substantially. The current value dropped considerably because the nichrome wire was fusion-cut, but the current value started to rise again as the applied voltage was increased, leading to the ignition of the sealing resin in due course. It was determined that the occurrence of the ignition was when the flame from the sealing resin was visually confirmed, and the time measurement by the stopwatch was terminated at that time. When the flame was confirmed, the power source was turned off to prevent fire from spreading, and the test sample was extinguished.

Thus, the time period from the time when the nichrome wire was fusion-cut and the current value dropped substantially to the time when the ignition was measured by the stopwatch. And in FIG. 7, the amount of electric power required from the time when the nichrome wire was fusion-cut to the time of ignition of the sealing resin was determined by multiplying the voltage value and the current value at each point in time of portion C. Thus, the amounts of electric power required from the time when the nichrome wire was fusion-cut to the time of ignition determined on the three types of sealing resins (1) to (3) shown in Table 3 are shown in Table 4.

TABLE 4

| | | Sealing | Sealing | Sealing |
|---|---|---|---|---|
| | | resin (1) | resin (2) | resin (3) |
| Amount | Maximum | 1113.0 | 1062.1 | 698.9 |
| of | Minimum | 689.9 | 694.0 | 356.2 |
| electric | Average | 858.9 | 823.6 | 542.2 |
| power | | | | |
| (Ws) | | | | |

It was confirmed from the calculated results shown in Table 4 that the amount of electric power required in the period from the time when the heating element nichrome wire was fusion-cut to the time of ignition of the sealing resin is variable depending on the types of sealing resins. And, in comparison with the sealing resin (2) which was the same type as the resin C which was hard to ignite, the sealing resin (3) which was a resin of the same type as the resin B which easily had ignition by the overcurrent test had a reduced amount of electric power required in the period from the time when the nichrome wire was fusion-cut to the ignition of the sealing resin. It was confirmed from the above that the ignition is readily caused by heating from the inside as the amount of electric power required from the time when the nichrome wire was fusion-cut to the time of ignition of the sealing resin is smaller. And, it became obvious that the flame retardancy of the sealing resin can be quantitatively indicated by an index according to the method of evaluating the flame retardancy of the invention.

The structure, shape, size and disposed relationships described in the embodiments are merely described roughly, and the compositions (materials) of the individual structures are mere examples. Therefore, the present invention is not limited to the embodiments described above, and it is to be understood that modifications and variations of the embodiments can be made without departing from the spirit and scope of the invention.

What is claimed is:

1. A method of evaluating the flame retardancy of a sealing resin, comprising:
heating and fusion cutting a heating element of a test sample by passing electric current to the heating element to cause the heating element to generate heat, the test sample having a layer formed of the sealing resin including the heating element therein;
igniting the sealing resin by continuing the passage of electric current to the heating element even after the heating element is fusion-cut; and
measuring a voltage and/or current applied in a period from the fusion cutting of the heating element to the ignition of the sealing resin.

2. The method of evaluating the flame retardancy of a sealing resin according to claim 1,
wherein the measuring of the voltage and/or current has calculating an amount of electric power applied in a period from the fusion cutting of the heating element to the ignition of the sealing resin.

3. The method of evaluating the flame retardancy of a sealing resin according to claim 2, further comprising,
judging and evaluating the flame retardancy of the sealing resin by using as an index the amount of electric power calculated.

4. The method of evaluating the flame retardancy of a sealing resin according to claim 3,
wherein it is evaluated in judging and evaluating that the flame retardancy of the sealing resin is lower as the amount of electric power is smaller.

5. The method of evaluating the flame retardancy of a sealing resin according to claim 1,
wherein the heating and fusion cutting has passing electric current to the heating element while varying the applied voltage.

6. The method of evaluating the flame retardancy of a sealing resin according to claim 1, further comprising,
preheating the sealing resin by applying a voltage to it before the heating and fusion cutting.

7. The method of evaluating the flame retardancy of a sealing resin according to claim 6,
wherein the voltage applied in preheating is adjusted according to the characteristics of the sealing resin.

8. The method of evaluating the flame retardancy of a sealing resin according to claim 6,
wherein the voltage applied in preheating is determined to provide a preheating level enough to ignite the sealing resin without fail in the ignition step.

9. The method of evaluating the flame retardancy of a sealing resin according to claim 1,
wherein a cabonized portion is formed in the sealing resin after the heating element is fusion-cut, and the passage of electric current is continued through the cabonized portion.

10. The method of evaluating the flame retardancy of a sealing resin according to claim 5,
wherein the applied voltage is increased at a voltage increasing rate of a level that the passage of electric current is continued as the cabonized portion is formed in the sealing resin even after the heating element is fusion-cut in the heating and the fusion cutting.

11. The method of evaluating the flame retardancy of a sealing resin according to claim 1,
wherein the ignition has visually checking the flame from the sealing resin.

12. A test sample for evaluation of flame retardancy used in the method of evaluating the flame retardancy of a sealing resin according to claim 1, comprising:
a heating wire;
conducting terminals formed of metal having an electric resistance lower than the heating wire and connected to both ends of the heating wire; and
a sealing resin layer covered on the outer periphery of the heating wire and a portion of the each conducting terminal.

13. The test sample for evaluation of flame retardancy according to claim 12,
wherein the conducting terminals are tubular or rod-like and compression-bonded to both ends of the heating wire.

14. The test sample for evaluation of flame retardancy according to claim 12,
wherein connection points between the heating wire and the conducting terminals have a resistance value which is not larger than a prescribed value.

15. The test sample for evaluation of flame retardancy according to claim 12,
wherein the sealing resin layer is molded on the outer periphery of the heating wire.

16. The test sample for evaluation of flame retardancy according to claim 12,
wherein the sealing resin layer has a thickness on one side 2 to 5 times larger than the other side when it is split by a plane passing across the heating wire.

17. The test sample for evaluation of flame retardancy according to claim 16,
wherein ignition is caused on the thinner side of the sealing resin layer.

18. The test sample for evaluation of flame retardancy according to claim 17,
wherein the thinner side of the sealing resin layer has a thickness of 1 to 1.2 mm.

19. A semiconductor device, comprising:
a substrate;
a semiconductor chip mounted on the substrate;
external connection terminals;
bonding wires electrically connecting the semiconductor chip and the external connection terminals; and
a sealing resin layer formed over the bonding wires and connection points between the bonding wires and the semiconductor chip,
wherein the sealing resin layer is formed of the sealing resin which is evaluated as highly flame retardant by the method of evaluating the flame retardancy according to claim 3.

20. A method of producing a semiconductor device, comprising:
mounting a semiconductor chip on a substrate;
electrically connecting the semiconductor chip and external connection terminals through bonding wires; and
forming a sealing resin layer over the bonding wires and connection points between the bonding wires and the semiconductor chip,
wherein the forming of the sealing resin layer has forming the sealing resin which is evaluated as highly flame retardant by the method of evaluating the flame retardancy according to claim 3.
